(19) United States
(12) Patent Application Publication
(10) Pub. No.: US 2011/0180938 A1
(43) Pub. Date: Jul. 28, 2011

(54) ELECTRONIC DEVICE AND METHOD OF MANUFACTURING THE SAME

(75) Inventors: Kazuya HIRASAWA, Obu-city (JP); Yuuji Ootani, Okazaki-city (JP); Akiyoshi Asai, Aichi-gun (JP); Hirokazu Imai, Okazaki-city (JP); Hiroyoshi Kunieda, Nukata-gun (JP); Harumi Kodama, Sodegaura-city (JP); Masayuki Onishi, Ichihara-city (JP); Ryo Sakaguchi, Ichihara-city (JP); Kazumi Nakayoshi, Sodegaura-city (JP)

(73) Assignees: DENSO CORPORATION, Kariya-city (JP); Dow Corning Toray Co., Ltd., Tokyo (JP)

(21) Appl. No.: 13/005,741

(22) Filed: Jan. 13, 2011

(30) Foreign Application Priority Data
Jan. 28, 2010 (JP) 2010-16844

(51) Int. Cl. H01L 23/48; H01L 21/50

(52) U.S. Cl. 257/778; 156/329; 257/E23.01; 257/E21.499

(57) ABSTRACT

In an electronic device, a silicone adhesive bonding first and second members is made from a composition comprising: (A) 100 parts by mass of an organopolysiloxane containing in one molecule at least two alkenyl groups and being free of silicon-bonded hydroxyl and alkoxy groups wherein the content of cyclic siloxanes having 4 to 20 siloxane units is at most 0.1 mass %; (B) an organopolysiloxane containing in one molecule at least two silicon-bonded hydrogen atoms and being free of an alkenyl group, and silicon-bonded hydroxyl and alkoxy groups; (C) at least 0.05 parts by mass of an adhesion promoter; (D) 100 to 2000 parts by mass of a thermally conductive filler; and (E) a hydrosilylation-reaction catalyst. (B) is contained such that the silicon-bonded hydrogen atoms is in the range of 0.5 to 10 mol per 1 mol of the alkenyl groups of (A), and the sum of (B) and (C) is 0.5 to 10 mass % of the sum of (A), (B) and (C).

### CROSS REFERENCE TO RELATED APPLICATION

This application is based on Japanese Patent Application No. 2010-16844 filed on Jan. 28, 2010, the disclosure of which is incorporated herein by reference.

### FIELD OF THE INVENTION

The present invention relates to an electronic device having a bonding structure using a silicone adhesive and a method of manufacturing the same.

### BACKGROUND OF THE INVENTION

With regard to such an electronic device, in general, a first member and a second member, such as a circuit board and a heat sink, are bonded to each other by curing a silicone adhesive with heat between the first member and the second member.

On the circuit board, for example, electronic components are connected through an electrically conductive paste and the like, and connecting structures are formed by wire bonding, flip chip bonding and the like. Further, the circuit board and the electronic components are sealed with a mold resin. Therefore, various drawbacks, such as defective sealing, defective bonding connection, defective connection of the electrically conducive paste, are likely to occur due to siloxane gas generated when the silicone adhesive is heated for curing.

To solve such drawbacks, an electronic device using an adhesive that generate less siloxane gas has been desired. Also, there are siloxane compositions having a reduced content of low molecular weight siloxane so as to reduce the emission rate of siloxane. Such siloxane compositions are, for example, described in Japanese Unexamined Patent Application Publication No. 03-157474 (having counterpart U.S. Pat. No. 5,145,931) and Japanese Unexamined Patent Application Publication No. 04-311764.

However, even if such siloxane compositions having the reduced content of low molecular weight siloxane are used for the adhesive of the electronic device, it is difficult to sufficiently reduce the above drawbacks.

### SUMMARY OF THE INVENTION

The present invention is made in view of the foregoing matter, and it is an objective of the present invention to provide an electronic device in which a first member and a second member are bonded to each other through a silicone adhesive, which has a reduced emission rate of siloxane gas during heating, and a method of manufacturing the electronic device.

In order to achieve the above objective, the present inventors made an intensive study focusing on a composition of silicone adhesive and reached the present invention.

According to an aspect of the present invention, an electronic device comprises a first member, a second member disposed along the first member and a silicone adhesive bonding the first member and the second member. The silicone adhesive is made from a composition comprising: (A) 100 parts by mass of an organopolysiloxane that contains in one molecule at least two alkenyl groups, that is free of a silicon-bonded hydroxyl group and a silicon-bonded alkoxy group, and in which the content of cyclic siloxanes having from 4 to 20 siloxane units is equal to or less than 0.1 mass %; (B) an organopolysiloxane that contains in one molecule at least two silicon-bonded hydrogen atoms and that is free of an alkenyl group, and a silicon-bonded hydroxyl group and a silicon-bonded alkoxy group; (C) at least 0.05 parts by mass of an adhesion promoter; (D) 100 to 2000 parts by mass of a thermally conductive filler; and (E) a hydrosilylation-reaction catalyst. In the composition, component (B) is contained in such an amount that the amount of silicon-bonded hydrogen atoms is in the range of 0.5 to 10 mol per 1 mol of the alkenyl groups of component (A). Further, the sum of components (B) and (C) is in the range of 0.5 to 10 mass % of the sum of components.(A), (B) and (C).

In the electronic device using the silicone adhesive made from the above composition, the emission rate of siloxane gas during the heating of the silicone adhesive is sufficiently reduced.

The electronic device having the above silicone adhesive is manufactured by placing the first member and the second member on top of each other through the composition, and heating the composition in one of a vacuum environment and an evacuation environment. In such a method, in addition to the effect of reducing the emission rate of the siloxane gas, it is less likely that the siloxane gas will adhere to surfaces of parts on one of the first member and the second member.

### BRIEF DESCRIPTION OF THE DRAWINGS

Other objects, features and advantages of the present invention will become more apparent from the following detailed description made with reference to the accompanying drawings, in which like parts are designated by like reference numbers and in which:

FIG. 1 is a schematic sectional view of an electronic device according to a first embodiment of the present invention;

FIG. 2 is a graph showing an experimental result of the amount of reduction of a silicone adhesive due to volatilization during heating according to the first embodiment;

FIG. 3 is a schematic sectional view of a main part of an electronic device according to a second embodiment of the present invention;

FIG. 4 is a schematic sectional view of an electronic device according to a third embodiment of the present invention; and

FIG. 5 is a schematic sectional view of an electronic device according to a fourth embodiment of the present invention.

### DETAILED DESCRIPTION OF EXEMPLARY EMBODIMENTS

Hereinafter, embodiments of the present invention will be described with reference to the drawings. Like parts are designated with like reference numerals, and a description thereof will not be repeated.

### First Embodiment

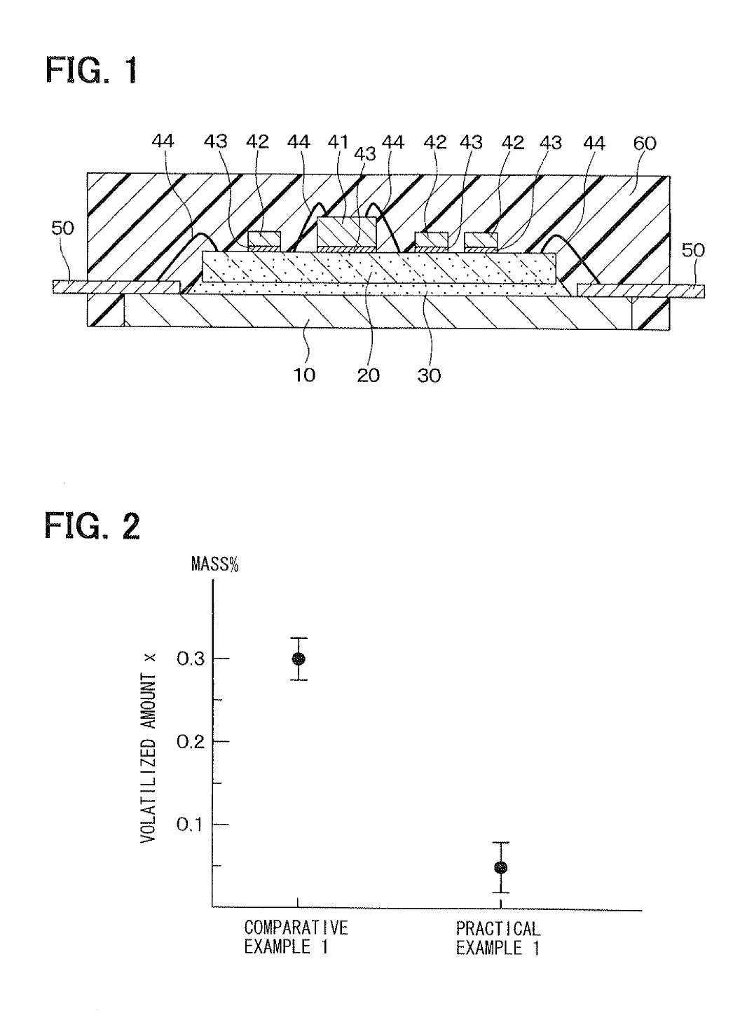

Referring to FIG. 1, in an electronic device according to the first embodiment, a substrate 20 is mounted on a surface, such as a top surface in FIG. 1, of a heat sink 10 through a silicone adhesive 30.

The heat sink 10, which is for example constituted as a first member, is a plate member having heat radiation performance. A material of the heat sink 10 is optimally selected, such as from Fe, Al, Cu, a Cu-Mo alloy, and an Al-SiC complex. In a case where the heat sink 10 is made of Fe, the surfaces thereof may be plated with Ni.

The substrate 20 is a common circuit board, and is for example constituted as a second member. The substrate 20 has a plate shape having a front surface, such as a top surface in FIG. 1, and a rear surface, such as a bottom surface in FIG. 1.

The silicone adhesive 30 is disposed along the rear surface of the substrate 20 to bond the rear surface to the heat sink 10. The substrate 20 is optimally selected, such as from an alumina substrate, an epoxy substrate, a glass epoxy substrate, and a glass composite substrate.

The silicone adhesive 30 is employed to bond the heat sink 10 and the substrate 20 to each other. Features of the silicone adhesive 30, such as a composition, will be described later in detail.

The heat sink 10 and the substrate 20 are bonded by curing the silicone adhesive 30 with heat. For example, the silicone adhesive 30 is first applied to the surface of the heat sink 10, and then the rear surface of the substrate 20 is attached to the surface of the heat sink 10. Thereafter, when the silicone adhesive 30 is heated, the heat sink 10 and the substrate 20 are bonded to each other by the cured silicone adhesive 30. As another example, the silicone adhesive 30 is first applied to the rear surface of the substrate 20, and then the rear surface of the substrate 20 is attached to the surface of the heat sink 10. Thereafter, when the silicone adhesive 30 is heated, the heat sink 10 and the substrate 20 are bonded to each other by the cured silicone adhesive 30. The silicone adhesive 30 is applied by an optimal method, such as by screen printing, dispensing, or stamping.

It is noted that rising of the silicone adhesive 30 from the rear surface toward the front surface of the substrate 20 along a side thereof, which is between the front surface and the rear surface, is equal to or less than a half of a thickness of the substrate 20.

For example, a load and time for attaching the substrate 20 to the heat sink 10 are suitably determined in such a manner that the rising of the silicone adhesive 30 is equal to or less than a half of the thickness of the substrate 20.

On the front surface of the substrate 20, elements such as an IC chip 41 and passive component parts 42 including a capacitor and a resistance are mounted through an electrically conductive bonding material 43, which is made from common electrically conductive paste or solder. The IC chip 41 and the passive component part 42 are connected to the substrate 20 through the electrically conductive bonding material 43.

Further, the IC chip 41 is connected to the front surface of the substrate 20 through bonding wires 44. In addition, a conductive lead frame 50 is disposed beside the substrate 20. The lead frame 50 is made of a conductive material, such as Cu or Fe.

The lead frame 50 is connected to the substrate 20 through the bonding wires 44. A material of the bonding wires 44 is optimally selected from metals that includes Al, Au, and Cu as a main component, in which Pd, Si or the like can be added in some cases.

The heat sink 10, the substrate 20, the members 41 to 44 mounted on the substrate 20, and the lead frame 50 are sealed with a mold resin 60, which is for example made of an epoxy resin. The mold resin 60 is formed by a common method, such as by transfer molding.

An opposite surface of the heat sink 10, that is, the bottom surface in FIG. 1, is exposed from the mold resin 60. Ends of the lead frame 50 opposite to the bonding wires 44 are also exposed from the mold resin 60 to be connected to external devices as outer leads. For example, a portion of the heat sink 10, which is sealed with the mold resin 60, may be formed with a groove. The groove may be formed at a location 1 to 2 mm from the edge of the portion of the heat sink 10.

To produce the electronic device having the aforementioned structure, for example, the substrate 20 is attached to the heat sink 10 through the silicone adhesive 30, and then the silicone adhesive 30 is cured by heating. Thus, the substrate 20 is bonded to the heat sink 10 with the silicone adhesive 30. Thereafter, the component parts 41, 42 are joined to the substrate 20 through the electrically conductive bonding material 43, and desired portions are connected through the bonding wires 44 by wire bonding. Further, the heat sink 10, the substrate 20, the component parts 41, 42 and the lead frame 50 are sealed with the mold resin 60.

The electronic device produced in the aforementioned manner thus has a sealing structure by the mold resin 60, a connecting structure by the wire bonding, and a connecting structure by the electrically conductive bonding material 43 made from the electrically conductive paste or the solder.

Next, the silicone adhesive 30 according to the first embodiment will be described in detail. The silicone adhesive 30 is a thermally conductive silicone rubber composition having the following composition before polymerization by heating.

The composition comprises: (A) 100 parts by mass of an organopolysiloxane that contains in one molecule at least two alkenyl groups, that is free of a hydroxyl group bonded to a silicon atom and an alkoxy group bonded to a silicon atom, and in which the content of cyclic siloxanes having from 4 to 20 siloxane units is equal to or less than 0.1 mass %; (B) an organopolysiloxane that contains in one molecule at least two silicon-bonded hydrogen atoms and that is free of an alkenyl group, a hydroxyl group bonded to a silicon atom and an alkoxy group bonded to a silicon atom; (C) at least 0.05 parts by mass of an adhesion promoter such as a common silane coupling agent; (D) 100 to 2000 parts by mass of a thermally conductive filler such as alumina; and (E) a hydrosilylation-reaction catalyst. In the silicone adhesive 30 before the polymerization, the component (B) is contained in such an amount that the amount of the silicon-bonded hydrogen atoms is in the range of 0.5 to 10 mol per 1 mol of the alkenyl groups of the component (A). Further, the sum of components (B) and (C) is in the range of 0.5 to 10 mass % of the sum of components (A), (B) and (C).

The organopolysiloxane of the component (A) is a basis of the composition. The organopolysiloxane has at least two alkenyl groups in one molecule, and does not have a silicon-bonded hydroxyl group and a silicon-bonded alkoxy group.

The alkenyl groups of the component (A) are exemplified by vinyl, allyl, butenyl, pentenyl, hexenyl, and heptenyl groups, of which vinyl groups are preferable. Silicon-bonded organic groups other than the alkenyl groups of the component (A) are exemplified by; alkyl groups such as methyl, ethyl, propyl, butyl, pentyl, hexyl, and heptyl groups; aryl groups such as phenyl, tolyl, xylyl, and naphthyl groups; aralkyl groups such as benzyl, and phenethyl groups; and halogenated alkyl groups such as chloromethyl, 3-chloropropyl, and 3,3,3-trifluoropropyl groups, of which methyl and phenyl groups are preferable.

There are no special restrictions with regard to the molecular structure of the component (A), and the component (A) exemplary has a linear, partly branched linear, or branched molecular structure. The component (A) preferably has a linear molecular structure.

There are no special restrictions with regard to the viscosity of the component (A) at 25° C., but it is recommended that the viscosity be in the range of 10 to 500,000 mPa·s, and preferably 50 to 100,000 mPa·s. If the viscosity is equal to or higher than the lower limit of the recommended range, a cured body obtained by heating the composition has favorable physical characteristics. Further, if the viscosity is equal to or lower than the upper limit of the recommended range, handling workability of the composition improves.

Moreover, it is necessary that the content of cyclic siloxanes having from 4 to 20 siloxane units in the component (A) is equal to or less than 0.1 mass %, and is preferably equal to or less than 0.05 mass %. If the content of the cyclic siloxanes having from 4 to 20 siloxane units in the component (A) is equal to or lower than the upper limit of the aforementioned range, the emission rate of siloxane gas during the heating can be reduced as much as possible, as shown in an experimental result of FIG. 2. The cyclic siloxanes are exemplified by cyclic dimethylsiloxane oligomer, cyclic methylvinylsiloxane oligomer, cyclic methylphenylsiloxane oligomer, and a copolymerization oligomer of cyclic dimethylsiloxane and methylvinylsiloxane. The content of the cyclic siloxanes having from 4 to 20 siloxane units in the component (A) can be measured by gas chromatographic analysis or the like.

The following are examples of the organopolysiloxane of the component (A); a copolymer of dimethylsiloxane and methylvinylsiloxane capped at both molecular terminals with trimethylsiloxy groups; methylvinylpolysiloxane capped at both molecular terminals with trimethylsiloxy groups; a copolymer of dimethylsiloxane, methylvinylsiloxane and methylphenylsiloxane capped at both molecular terminals with trimethylsiloxy groups; dimethylpolysiloxane capped at both molecular terminals with dimethylvinylsiloxy groups; methylvinylpolysiloxane capped at both molecular terminals with dimethylvinylsiloxy groups; a copolymer of dimethylsiloxane and methylvinylsiloxane capped at both molecular terminals with dimethylvinylsiloxy groups; a copolymer of dimethylsiloxane, methylvinylsiloxane and methylphenylsiloxane capped at both molecular terminals with dimethylvinylsiloxy groups; an organopolysiloxane copolymer consisting of siloxane units represented by the formula R¹₃SiO_{1/2}, siloxane units represented by the formula R¹₂R²SiO_{1/2}, siloxane units represented by the formula R¹₂SiO_{2/2}, and a small amount of siloxane units represented by the formula SiO_{4/2}; an organopolysiloxane copolymer consisting of siloxane units represented by the formula R¹₂R²SiO_{1/2}, siloxane units represented by R¹₂SiO_{2/2}, and a small amount of siloxane units represented by the formula SiO_{4/2}; an organopolysiloxane copolymer consisting of siloxane units represented by the formula R¹R²SiO_{2/2}, a small amount of siloxane units represented by the formula R¹SiO_{3/2} or siloxane units represented by the formula R²SiO_{3/2}; and mixture of two or more sorts of these organopolysiloxanes.

In the above formulas, R¹ represents a monovalent hydrocarbon group other than an alkenyl group, and which is exemplified by alkyl groups such as methyl, ethyl, propyl, butyl, pentyl, hexyl, and heptyl groups; aryl groups such as phenyl, tolyl, xylyl, and naphthyl groups; aralkyl groups such as benzyl, and phenethyl groups; halogenated alkyl groups such as chloromethyl, 3-chloropropyl, and 3,3,3-trifluoropropyl groups. In the above formulas, R² represents an alkenyl group, and which is exemplified by vinyl, allyl, butenyl, pentenyl, hexenyl, and heptenyl groups.

The organopolysiloxane of the component (B) is a cross-linking agent of the composition, and has at least two silicon-bonded hydrogen atoms in one molecule, and does not have an alkenyl group, a hydroxyl group bonded to a silicon atom and an alkoxy group bonded to a silicon atom. Silicon-bonded organic groups of the component (B) are exemplified; by alkyl groups' such as methyl, ethyl, propyl, butyl, pentyl, hexyl, and heptyl groups; aryl groups such as phenyl, tolyl, xylyl, and naphthyl groups; aralkyl groups such as benzyl, and phenethyl groups; halogenated alkyl groups such as chloromethyl, 3-chloropropyl, and 3,3,3-trifluoropropyl groups, of which methyl and phenyl groups are preferable.

There are no special restrictions with regard to the molecular structure of the component (B), and the component (B) exemplary has a linear, partly branched linear, or branched molecular structure. The component (B) preferably has a linear molecular structure.

There are no special restrictions with regard to the viscosity of the component (B) at 25° C., but it is recommended that the viscosity is in the range of 1 to 500,000 mPa·s, and preferably 5 to 100,000 mPa·s. If the viscosity is equal to or higher than the lower limit of the recommended range, the cured body obtained by heating the composition has favorable physical characteristics. Further, if the viscosity is equal to or lower than the upper limit of the recommended range, handling workability of the composition improves.

The following are examples of the organopolysiloxane of the component (B): methylhydrogenpolysiloxane capped at both molecular terminals with trimethylsiloxy groups; a copolymer of dimethylsiloxane and methylhydrogensiloxane capped at both molecular terminals with trimethylsiloxy groups; a copolymer of dimethylsiloxane, methylhydrogensiloxane and methylphenylsiloxane capped at both molecular terminals with trimethylsiloxy groups; dimethylpolysiloxane capped at both molecular terminals with dimethylhydrogensiloxy groups; a copolymer of dimethylsiloxane and methylphenylsiloxane capped at both molecular terminals with dimethylhydrogensiloxy groups; methyiphenylpolysiloxane capped at both molecular terminals with dimethylhydrogensiloxy groups; an organopolysiloxane copolymer consisting of the siloxane units represented by the formula R¹₃SiO_{1/2}, siloxane units represented by the formula R¹₂HSiO_{1/2}, and siloxane units represented by the formula SiO_{4/2}; an organopolysiloxane copolymer consisting of siloxane units represented by the formula R¹₂HSiO_{1/2} and siloxane units represented by the formula SiO_{4/2}; and an organopolysiloxane copolymer consisting of siloxane units represented by the formula R¹HSiO_{2/2}, and siloxane units represented by the formula R₁SiO_{3/2} or siloxane units represented by the formula HSiO_{3/2}; and mixture of two or more sorts of these organopolysiloxanes. In the above formula, R¹ represents a monovalent hydrocarbon group other than an alkenyl group, and the same groups as the above are exemplified.

The component (B) is contained in such an amount that the amount of the silicon-bonded hydrogen atoms is in the range of 0.5 to 10 mol per 1 mol of the alkenyl groups of component (A), preferably 0.5 to 5 mol, and more preferably 0.5 to 3 mol. If the component (B) is contained in such an amount that the amount of the silicon-bonded hydrogen atoms is equal to or higher than the lower limit of the above range, the composition can be sufficiently cured. If the component (B) is contained in such an amount that the amount of the silicon-bonded hydrogen atoms is equal to or lower than the upper limit of the above range, the change in the physical characteristic of the cured body of the composition over time can be reduced.

The component (C) is an adhesion promoter for imparting a property of adhesion to the composition. Although there are no special restrictions with regard to the component (C), the component (C) is preferably an organosilicon compound containing an alkoxy group bonded to a silicon atom. The silicon-bonded alkoxy group of the component (C) is exemplified by methoxy, ethoxy, propoxy, and butoxy groups, of which the methoxy group is preferable. Silicon-bonded organic groups of the component (C) are exemplified by alkyl groups, such as methyl, ethyl, propyl, butyl, hexyl, and octyl groups; alkenyl groups, such as vinyl, allyl, and hexenyl groups; aryl groups, such as phenyl, tolyl, and xylyl groups; halogenated alkyl groups, such as 3,3,3-trifluoropropyl, and 3-chloropropyl groups; functional organic groups, such as 3-glycidoxypropyl, 3-methacryloxypropyl, 3-aminopropyl, and N-(2-aminoethyl)-3-aminopropyl groups; alkoxysilylalkyl groups, such as trimethoxysilylethyl and methyldimethoxysilylethyl groups; and silicon-bonded hydrogen atoms.

The component (C) is preferably a mixture of (i) an organosilicon compound that contains a silicon-bonded alkoxy group and has a boiling point of equal to or higher than 100° C. and (ii) a diorganosiloxane oligomer that contains in one molecule at least one alkenyl group and silicon-bonded hydroxyl groups, or a condensation reaction of the constituents (i) and (ii).

The constituent (i) has the boiling point at 1 atmospheric pressure (standard boiling point) of equal to or higher than 100° C. If the boiling point is equal to or higher than 100° C., low boiling components volatilizing from the composition during the curing can be reduced.

The constituent (i) is exemplified by 3-glycidoxypropyltrimethoxysilane, 3-glycidoxypropylmethyldimethoxysiiane, 3-methacryloxypropyltrimethoxysilane, 3-methacryloxypropylmethyldimethoxysilane, 3-aminopropyltrimethoxysilane, 3-aminopropyltriethoxysilane, and N-(2-aminoethyl)-3-aminopropyltrimethoxysilane.

The constituent (ii) is a diorganosiloxane oligomer containing silicon-bonded hydroxyl groups (silanol groups). It is preferable that the content of the silanol groups is at most 9 mass %. If the content of the silanol groups is equal to or less than 9 mass %, the cured body has a property of favorable adhesion.

The constituent (ii) is exemplified by a methylvinylsiloxane oligomer capped at both molecular terminals with silanol groups, a copolymerization oligomer of dimethylsiloxane and methylvinylsiloxane capped at both molecular terminals with silanol groups, a copolymerization oligomer of methylvinylsiloxane and methylphenylsiloxane capped at both molecular terminals with silanol groups.

The content of the component (C) is at least 0.05 parts by mass per 100 parts by mass of the component (A). That is, the content of the component (C) is equal to or higher than 0.05 parts by mass. If the content of the component (C) is equal to or higher than the above value, the cured body has a property of favorable adhesion.

Further, in the composition, it is necessary that the sum of components (B) and (C) is in the range of 0.5 to 10 mass % of the sum of components (A), (B) and (C), preferably 0.5 to 7 mass %, and more preferably 0.5 to 3 mass %. If the sum of the components (B) and (C) is equal to or higher than the lower limit of the above range, the composition has favorable adhesion and curability. If the sum of the components (B) and (C) is equal to or lower than the upper limit of the range, the emission rate of the siloxane gas can be reduced as much as possible during the heating of the composition, as shown in the experimental result of FIG. 2.

The component (D) is a thermally conductive filler for imparting a property of thermal conductivity to the composition. As the component (D), metal oxide base powder, metal nitride base powder, or the like can be used so as to impart a property of electrical insulation to the composition. For example, aluminum oxide powder, zinc oxide powder, or aluminum nitride powder can be used.

In a case where the composition needs to have a property of electrical conductivity in the electronic device, electrically conductive powder such as metal base powder can be used. In such a case, for example, silver powder can be used.

Further, in the composition, it is preferable that the component (D) is finished by a silicon base finishing agent. The silicon base finishing agent is exemplified by: alkoxysilanes, such as methyltrimethoxysilane, vinyltrimethoxysilane, vinyltriethoxysilane, 3-glycidoxypropyltrimethoxysilane, 3-methacryloxypropyltrimethoxysilane, 3-aminopropyltrimethoxysilane, 3-aminopropyltriethoxysilane, and N-(2-aminoethyl)-3-aminopropyltrimethoxysilane; chlorosilanes, such as methyltrichlorosilane, dimethyldichlorosilane, and trimethylmonochlorosilane; silazanes, such as hexamethyldisilazane and hexamethylcyclotrisilazane; and siloxane oligomers, such as a dimethylsiloxane oligomer capped at both molecular terminals with silanol groups, a copolymer oligomer of dimethylsiloxane and methylvinylsiloxane capped at both molecular terminals with silanol groups, a methylvinylsiloxane oligomer capped at both molecular terminals with silanol groups, and a methylphenylsiloxane oligomer capped at both molecular terminals with silanol groups.

The finishing method is exemplified by: dry processing conducted by directly mixing the component (D) and the silicon base finishing agent; wet processing conducted by mixing the component (D) and the silicon base finishing agent with an organic solvent such as toluene, methanol, or heptane; and in-situ processing in which the component (D) is surface-treated by combining the component (D) in an mixture of the component (A) and the silicon base finishing agent or combining the silicon base finishing agent in a mixture of the components (A) and (D).

The content of the component (D) is in the range of 100 to 2,000 parts by mass per 100 parts by mass of the component (A), and preferably 200 to 1,600 parts by mass. If the content of the component (D) is equal to or higher than the lower limit of the above range, the cured body of the composition has sufficient thermal conductivity. If the content of the component (D) is equal to or lower than the upper limit of the above range, the composition has improved handleability.

The component (E) is a hydrosilylation-reaction catalyst for promoting curing of the composition. The component (E) is exemplified by platinum fine powder, platinum black, platinum on fine silica powder, platinum on active carbon, chloroplatinic acid, platinum tetrachloride, alcohol solutions of chloroplatinic acid, platinum-olefin complexes, complexes of platinum and alkenylsiloxane, such as 1,3-divinyl-1,1,3,3-tetramethyldisiloxane, or similar platinum base catalysts; tetrakis (triphenylphosphine) palladium, or similar palladium base catalysts; rhodium base catalysts, and thermoplastic resin powder of such as polystyrene, nylon, polycarbonate, or silicone, which contains the above metal base catalysts and has a particle diameter less than 10 μm.

The component (E) is used in a catalytic quantity. For example, it is recommended to use the component (E) in such an amount that the amount of the metallic atoms of the component (E) is in the range of 0.00001 to 0.05 mass % of the component (A), preferably 0.0001 to 0.005 mass %. If the content of the component (E) is equal to or higher than the lower limit of the above recommended range, curability of the composition improves. Even if the content of the component (E) is equal to or lower than the upper limit of the above recommended range, sufficient curability is achieved.

The composition is prepared by uniformly mixing the aforementioned components (A) through (E). Further, the composition can contain other arbitrary components.

For example, it is possible to contain curing inhibitors so as to improve handleability of the composition. The curing inhibitors are exemplified by; alkyne alcohols such as 2-methyl-3-butyn-2-ol, 3,5-dimethyl-1 -hexyn-3-ol, and 2-phenyl-3-butyn-2-ol; en-yne compounds such as 3-methyl-3-penten-1-yne, and 3,5-dimethyl-3-hexen-1-yne; and benzotriazole. The content of the aforementioned curing inhibitors preferably in the range of 10 to 50,000 ppm in mass units in the composition.

In manufacturing the electronic device, the silicone adhesive 30 having the aforementioned composition is cured by heating. It is preferable to perform the heating in a vacuum or evacuation environment.

With regard to the heating in the vacuum environment, for example, a work is placed in a vacuum vessel or the like, and an inside of the vessel is made in a vacuum state by a vacuum pump or the like. The heating is performed in such a vacuum state.

With regard to the heating in the evacuation environment, for example, an exhaust duct is set near a work, and the heating is performed while generating the flow of evacuation by a pump or the like.

The silicone adhesive 30 is intended to minimize the emission rate of the siloxane gas during the heating. The effect will be hereinafter described in detail with reference to the experimental result found by the present inventors.

FIG. 2 shows the experimental result where the amount of reduction due to volatilization during the heating was examined with respect to a common silicone adhesive and the silicone adhesive 30 of the embodiment. As the common silicone adhesive, a composition of later-described comparative example 1 is used. As the silicone adhesive 30 of the embodiment, a composition of later-described practical example 1 is used. Samples of the silicone adhesives are heated at 150° C. for 17 hours, and the amount of mass reduction due to the volatilization (heating loss) after the heating with respect to the mass before the heating was examined.

Specifically, the mass before the heating is defined as 100 mass %. The amount obtained by deducting the mass after the heating from the mass before the heating is defined as the volatilized amount x, and the percentage of the volatilized amount x is calculated. It is noted that most of the volatilized amount x is the siloxane gas.

As shown in FIG. 2, the amount of reduction of the common silicone adhesive using the composition of the comparative example 1 was 0.3 mass %. On the other hand, the amount of reduction of the silicone adhesive 30 using the composition of the practical example 1 as the embodiment was 0.05 mass % on average, and was at most 0.1 mass %. That is, in the silicone adhesive 30 using the composition of the practical example 1 as the embodiment, the amount of reduction by the volatilization after the heating at 150° C. for 17 hours is equal to or less than 0.1 mass %. It is noted that the similar result was obtained in an experiment using a composition of later-described practical example 2 as the silicone adhesive of the embodiment.

Accordingly, by using the composition having the components (A) through (E) with the aforementioned composition rates as the silicone adhesive 30, the emission rate of the siloxane gas is remarkably reduced, as compared with that of the common silicone adhesive. That is, in the first embodiment using the silicone adhesive 30, the emission rate of the siloxane gas during the heating can be minimized.

The electronic device has the sealing structure of the mold resin 60, and thus the silicone adhesive 30 needs to be cured by heating before the sealing of the mold resin 60. Also in such a case, since the emission rate of the siloxane gas is reduced, the amount of siloxane gas adhering to the components to be sealed with the mold resin 60 can be reduced. As such, it is less likely that the defective sealing will occur, and the electronic device having excellent functions can be provided.

In such a case, a polyamide resin, which is generally applied to surfaces of the components to be sealed with the mold resin 60 so as to ensure the property of sealing, is not necessary. Therefore, the manufacturing costs can be reduced. That is, the electronic device that does not have the polyamide resin on the surfaces of the components to be sealed with the mold resin 60 can be implemented.

The effects of improvement of sealing of the mold resin 60 will be described in detail based on the experimental result found by the inventors. Sealing conditions were examined with regard to three electronic devices, such as a first comparative model, a second comparative model and a practical model.

The first comparative model had the similar structure as the device shown in FIG. 1, but the composition of the later-described comparative example 1 was used as the silicone adhesive 30. The second comparative model had the polyamide resin, in addition to the structure of the first comparative model. In the second comparative model, the mold resin 60 was formed after the polyamide resin was applied to the surfaces of the components to be sealed. The practical model as the embodiment had the similar structure as the device shown in FIG. 1, and the composition of the later-described practical example 1 was used as the silicone adhesive 30.

Thirty samples were prepared for each of the practical model and the first and second comparative models. Cold-heat cycles of −55° C. to 150° C. were applied to each of the samples for 1000 cycles. Thereafter, existence of separation of the mold resin 60 was examined in each sample using an ultrasonic exploration apparatus.

As a result, with regard to the first comparative model, the separation was found in seventeen of the thirty samples. No separation was found in the samples of the second comparative model and the practical model. In addition, no separation was found in samples in which the material having a composition of the later-described practical example 2 was used as the silicone adhesive 30. Accordingly, in the electronic device of the embodiment, the similar property of sealing of the mold resin 60 was achieved even if the polyamide resin to improve the property of sealing was not used.

The electronic device has the connecting structures of the wire bonding and the electrically conductive bonding material 43 made from the electrically conductive paste or the solder. Thus, the silicone adhesive 30 needs to be cured by heating before the wire bonding and the applying of the electrically conductive bonding material 43.

Even in such a structure, since the emission rate of the siloxane gas is minimized, the amount of adhesion of the siloxane gas to bonding lands and portions to which the electrically conductive bonding material 43 is to be applied is minimized. Therefore, it is less likely that defective connection will occur. Accordingly, the electronic device having excellent functions can be provided.

Moreover, as described in the above, it is configured that the rising of the silicone adhesive 30 along the side of the substrate 20 from the rear surface toward the front surface is equal to or less than the half of the thickness of the substrate 20. If the rising exceeds the half of the thickness of the substrate 20, the siloxane gas may easily reach the front surface of the substrate 20.

If the siloxane gas reaches the front surface of the substrate 20, it unfavorably adheres to the components to be sealed with the mold resin 60, the connecting portions of the wire bonding, the connecting portions of the electrically conductive bonding material 43 and the like. If the rising is limited to equal to or less than the half of the thickness of the substrate 20, such drawbacks can be reduced.

As described in the above, if the heating of the silicone adhesive 30 is conducted in the vacuum environment or the evacuation environment, it is less likely that the siloxane gas will adhere to the surfaces of the components.

### Second Embodiment

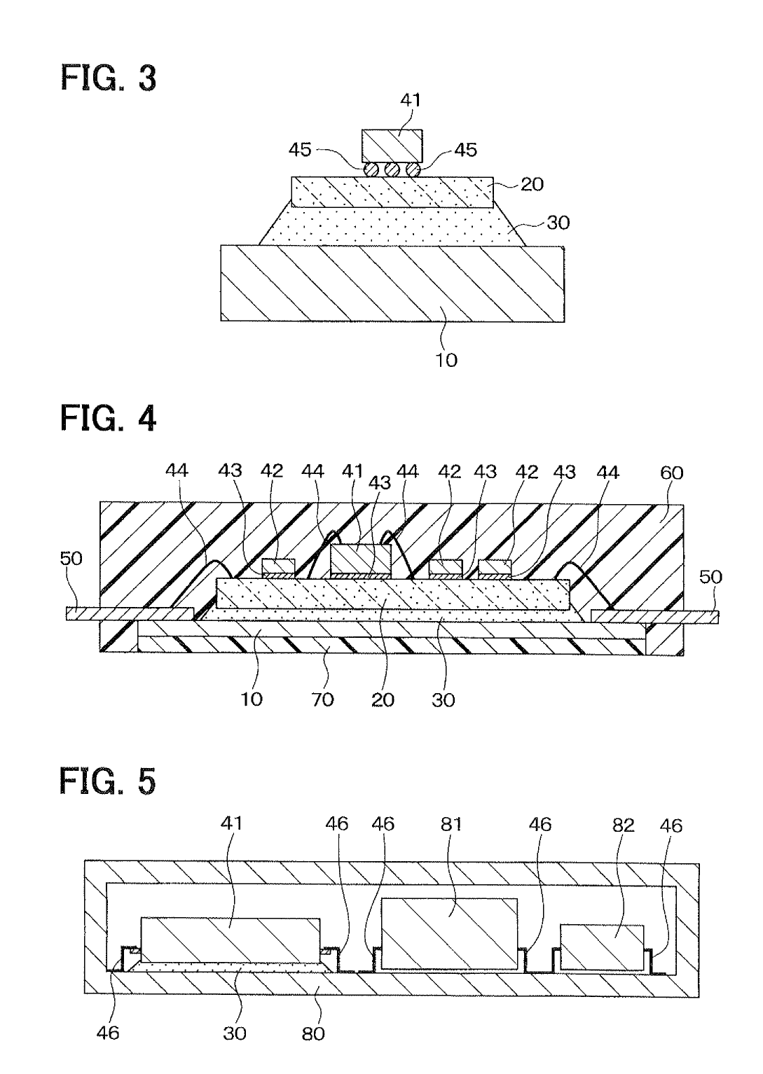

FIG. 3 shows a main part of an electronic device according to a second embodiment. A main difference of the electronic device of the second embodiment from the electronic device of the first embodiment is that the IC chip 41 is connected to the substrate 20 by flip-chip bonding.

As shown in FIG. 3, the IC chip 41 is connected to the substrate 20 through bumps 45 made of gold, copper or the like. In a case where the electronic device has a connecting structure of the flip-chip bonding, the silicone adhesive 30 needs to be cured by heating before the flip-chip bonding.

Also in this case, the aforementioned effect of the silicone adhesive 30 is demonstrated. That is, the emission rate of the siloxane gas is reduced, and thus the adhering of the siloxane gas to the bonding lands is minimized. Therefore, defective bonding connection is reduced. The electronic device having favorable functions can be achieved.

### Third Embodiment

FIG. 4 shows an electronic device according to a third embodiment. The electronic device shown in FIG. 4 has an insulating radiation sheet 70 along the heat sink 10 provided by a lead frame on a side opposite to the substrate 20. The insulating radiation sheet 70 uses a silicone resin, an epoxy resin or the like, as a main component. Other structures are similar to the electronic device of FIG. 1.

### Fourth Embodiment

FIG. 5 shows an electronic device according to a fourth embodiment. As shown in FIG. 5, the electronic device has a metallic housing 80 as the first member, and an electronic part 41 as the second member, such as an IC chip having a heat radiation property, is adhered to the housing 80 through the silicone adhesive 30, which is similar to the silicone adhesive 30 of the aforementioned embodiments.

In addition to the electronic part 41, a motor part 81 and a switch part 82, which have electrical contacts, are mounted in the housing 80. The electrical contacts of the parts 81, 82 are connected or disconnected by contacting or separating two elements.

The parts 41, 81, 82 are electrically connected through leads 46 and non-illustrated circuit provided in the housing 80. For example, the electronic part 41 controls the switch part 82 to drive the motor part 81.

In such a structure, the motor part 81 and the switch part 82, which have the electrical contacts, are located adjacent to the bonding structure of the silicone adhesive 30. Since the emission rate of the siloxane gas from the silicone adhesive 30 is minimized, the amount of siloxane gas adhering to the electrical contacts of the parts 81, 82 is minimized. Therefore, it is less likely that the electrical contacts will have defective connection. Accordingly, the electronic device having favorable functions can be achieved.

### Other Embodiments

The aforementioned silicone adhesive 30 can be employed to adhere a piezoelectric element, such as a ceramic oscillator, and an electrostatic element used for an accelerometer, an angular velocity sensor or the like to a substrate. Also in such cases, since the emission rate of the siloxane gas is minimized, an effect of avoiding characteristic change of the piezoelectric element and the electrostatic element due to the siloxane gas being adhered can be expected.

The first member and the second member are not limited to the aforementioned members, such as the heat sink 10, the housing 80 and the substrate 20. The first member and the second member can be any other members to be adhered to each other through the silicone adhesive 30.

Additional advantages and modifications will readily occur to those skilled in the art. The invention in its broader term is therefore not limited to the specific details, representative apparatus, and illustrative examples shown and described.

### EXAMPLES

The thermally conductive silicone rubber composition as the aforementioned silicone adhesive 30 will be explained more in detail with reference to the practical examples and the comparative example.

The values of viscosities used in the examples were measured at 25° C. The characteristics of the thermally conductive silicone rubber composition were evaluated as follows. The result of the amount of reduction (heating loss) due to the volatilization during the heating is shown in FIG. 2.

[Content of Cyclic Siloxanes Having from 4 to 20 Siloxane Units in Organopolysiloxane]

The cyclic siloxanes having from 4 to 20 siloxane units in the organopolysiloxane were extracted with acetone, and the amount extraction was measured by gas chromatography with a flame ionization detector (FID). The content of the cyclic siloxanes in the organopolysiloxane was calculated from the amount of extraction.

### [Heating Loss]

Approximately 5 g of the thermally conductive silicone rubber composition was placed in an aluminum cup, and the mass of the composition was accurately measured to four places of decimals. This aluminum cup was then heated in a hot air circulation oven for 17 hours at 150° C. to cure the composition. After the aluminum cup was cooled at room temperature for 30 minutes, the mass of the silicone rubber was accurately measured to four places of decimals and the heating loss (%) was calculated. it is noted that the curing of the composition is finished in a predetermined time, for example, within one four. In this case, however, the composition was heated for 17 hours so as to obtain a stable result.

### Practical Example 1

A silicone rubber base was prepared as follows: 100 parts by mass of dimethylpolysiloxane capped at both molecular terminals with dimethylvinylsiloxy groups, which contains 200 ppm of cyclic siloxanes having from 4 to 20 siloxane units and has a viscosity of 2,000 mPa·s, 4.3 parts by mass of methyltrimethoxysilane, and 330 parts by mass of unfixed form aluminum oxide particulates having an average particle diameter of 2.7 μm were mixed at room temperature by a Ross mixer; and then mixed while heating under a reduced pressure at 150° C. for 1 hour.

Next, a thermally conductive silicone rubber composition was prepared by adding the following materials (c1) through (c4) to the aforementioned silicone rubber base and uniformly mixing at room temperature: (c1) 0.7 parts by mass of an adhesion promoter that was prepared beforehand by mixing 3-glycidoxypropyltrimethoxysilane (boiling point 290° C.) and a copolymerization oligomer of dimethylsiloxane and methylvinylsiloxane capped at both molecular terminals with silanol groups having a viscosity of 20 mPa·s and containing 7 mass % of the silanol groups at a mass ratio of 1:1; (c2) 1.9 parts by mass of a copolymer of dimethylsiloxane and methylhydrogensiloxane capped at both molecular terminals with trimethylsiloxy groups having a viscosity of 5 mPa·s (corresponding to the amount that the silicon-bonded hydrogen atoms of this component is 1.4 mol per 1 mol of vinyl groups in the aforementioned dimethylpolysiloxane contained in the silicone rubber base); (c3) 0.1 parts by mass of 2-phenyl-3-butyn-2-ol; and (c4) a complex of platinum and 1,3-divinyltetramethyldisiloxane (with the amount that the metal platinum of this component is 30 ppm in mass units to the aforementioned dimethylpolysiloxane contained in the silicone rubber base). In the thermally conductive silicone rubber composition, the sum of the aforementioned copolymer of dimethylsiloxane and methylhydrogensiloxane and the aforementioned adhesion promoter was 2.4 mass % of the sum of the aforementioned dimethylpolysiloxane, the aforementioned copolymer of dimethylsiloxane and methylhydrogensiloxane, and the aforementioned adhesion promoter.

### Practical Example 2

A silicone rubber base was prepared as follows: 100 parts by mass of dimethylpolysiloxane capped at both molecular terminals with dimethylvinylsiloxy groups that contains 200 ppm of cyclic siloxanes having from 4 to 20 siloxane units and has a viscosity of 2,000 mPa·s, 4.3 parts by mass of methyltrimethoxysilane, and 330 parts by mass of unfixed form aluminum oxide particulates having an average particle diameter of 2.7 μm were mixed at room temperature by a Ross mixer; and then mixed while heating under a reduced pressure at 150° C. for 1 hour.

Next, a thermally conductive silicone rubber composition was prepared by adding the following materials (d1) through (d4) to the aforementioned silicone rubber base and uniformly mixing at room temperature: (d1) 0.2 parts by mass of an adhesion promoter that was prepared beforehand by mixing 3-glycidoxypropyltrimethoxysilane (boiling point 290° C.) and a copolymerization oligomer of dimethylsiloxane and methylvinylsiloxane capped at both molecular terminals with silanol groups having a viscosity of 20 mP·s and containing 7 mass % of the silanol groups at a ratio of 1:1; (d2) 0.6 parts by mass of methylhydrogenpolysiloxane capped at both molecular terminals with trimethylsiloxy groups having a viscosity of 5 mPa·s (corresponding to the amount that the silicon-bonded hydrogen atoms in this component is 1.1 mol per 1 mol of the vinyl groups in the aforementioned dimethylpolysiloxane contained in the silicone rubber base); (d3) 0.1 parts by mass of 2-phenyl-3-butyn-2-ol; and (d4) a complex of platinum and 1,3-divinyl-1,1,3,3-tetramethyldisiloxane (with the amount that the content of the metal platinum of this component was 30 ppm in mass units to the aforementioned dimethylpolysiloxane contained in the silicone rubber base).

In the thermally conductive silicone rubber composition, the sum of the aforementioned methylhydrogenpolysiloxane and the aforementioned adhesion promoter was 0.8 mass % of the sum of the aforementioned dimethylpolysiloxane, the aforementioned methylhydrogenpolysiloxane, and the aforementioned adhesion promoter.

### Comparative Example 1

A silicone rubber base was prepared as follows: 70 parts by mass of dimethylpolysiloxane capped at both molecular terminals with dimethylvinylsiloxy groups that has a viscosity of 9000 mP·s and contains 10 ppm of cyclic siloxanes having from 4 to 20 siloxane units; 30 parts by mass of dimethylpolysiloxane capped at both molecular terminals with dimethylvinylsiloxy groups that has a viscosity of 2000 mPa·s and contains 13,000 ppm of cyclic siloxanes having from 4 to 20 siloxane units; 4 parts by mass of methyltrimethoxysilane; and 310 parts by mass of unfixed form aluminum oxide particulates having an average particle diameter of 2.7 μm are mixed at room temperature by a Ross mixer, and then mixed while heating under a reduced pressure at 150° C. for 1 hour.

Next, a thermally conductive silicone rubber composition was prepared by adding the following materials (e1) through (e3) to the aforementioned silicone rubber base and uniformly mixing at room temperature: (e1) 5.2 parts by mass of an adhesion promoter in which 3-glycidoxypropyltrimethoxysilane (boiling point 290° C.) and a copolymerization oligomer of dimethylsiloxane and methylvinylsiloxane capped at both molecular terminals with silanol groups having a viscosity of 20 mPa·s and containing 7 mass % of the silanol groups was prepared beforehand at a mass ratio of 1:1 by condensation reaction with a basic catalyst; (e2) 13 parts by mass of a copolymer of dimethylsiloxane and methylhydrogensiloxane capped at both molecular terminals with dimethyihydrogensiloxy groups having a viscosity of 5 mPas (corresponding to the amount that the silicon-bonded hydrogen atoms of the component was 4.9 mol per 1 mol of the vinyl groups of the aforementioned dimethylpolysiloxane mixture contained in the silicone rubber base); and (e3) a complex of platinum and 1,3-divinyl-1,1,3,3-tetramethyldisiloxane (with the amount that the content of metal platinum was 30 ppm in mass units in this component of the aforementioned dimethylpolysiloxane mixture contained in the silicone rubber base).

In the thermally conductive silicone rubber composition, the sum of the aforementioned copolymer of dimethylsiloxane and methylhydrogensiloxane and the aforementioned adhesion promoter was 15.4 mass % of the sum of the aforementioned dymethylpolysiloxane mixture, the aforementioned copolymer of dimethylsiloxane and methylhydrogensiloxane and the aforementioned adhesion promoter.

What is claimed is:

1. An electronic device comprising:
a first member;
a second member disposed along the first member; and
a silicone adhesive disposed between the first member and the second member to bond the first member and the second member, wherein
the silicone adhesive is made from a composition comprising:
(A) 100 parts by mass of an organopolysiloxane that contains in one molecule at least two alkenyl groups and that is free of a silicon-bonded hydroxyl group and a silicon-bonded alkoxy group wherein the content of cyclic siloxanes having from 4 to 20 siloxane units is equal to or less than 0.1 mass %;
(B) an organopolysiloxane that contains in one molecule at least two silicon-bonded hydrogen atoms and that is free of an alkenyl group, a silicon-bonded hydroxyl group and a silicon-bonded alkoxy group;
(C) at least 0.05 parts by mass of an adhesion promoter;
(D) 100 to 2000 parts by mass of a thermally conductive filler; and
(E) a hydrosilylation-reaction catalyst, wherein
component (B) is contained in such an amount that the amount of silicon-bonded hydrogen atoms is in the range of 0.5 to 10 mol per 1 mol of the alkenyl groups of component (A), and
the sum of components (B) and (C) is in the range of 0.5 to 10 mass % of the sum of components (A), (B) and (C).

2. The electronic device according to claim 1, wherein when the composition is heated at 150° C. for 17 hours, an amount of reduction of the composition after heating is equal to or less than 0.1 mass % of the composition before the heating.

3. The electronic device according to claim 1, wherein the first member and the second member are molded by a resin.

4. The electronic device according to claim 1, further comprising a bonding wire connecting to the second member.

5. The electronic device according to claim 1, further comprising an electronic component connected to the second member by flip-chip bonding.

6. The electronic device according to claim 1, further comprising an electronic component and an electrically conductive bonding material bonding the electronic component to the second member, wherein the electrically conductive bonding material is made from one of an electrically conductive paste and a solder.

7. The electronic device according to claim 1, wherein
the second member is a substrate having a front surface, a rear surface opposite to the front surface and a side between the front surface and the rear surface,
the rear surface is bonded to the first member through the silicone adhesive such that a rising of the silicone adhesive from the rear surface toward the front surface along the side is equal to or less than a half of a thickness of the substrate.

8. The electronic device according to claim 1, further comprising a motor part and a switch part each having an electrical contact, wherein the motor part and the switch part are mounted on the first member adjacent to the second member.

9. A method of manufacturing an electronic device, comprising:
arranging a first member;
applying a silicone adhesive to a surface of the first member;
arranging a second member along the surface of the first member through the silicone adhesive; and
heating the silicone adhesive for curing, thereby to bond the first member and the second member, wherein
the silicone adhesive before the heating has a composition comprising:
(A) 100 parts by mass of an organopolysiloxane that contains in one molecule at least two alkenyl groups and that is free of a silicon-bonded hydroxyl group and a silicon-bonded alkoxy group wherein the content of cyclic siloxanes having from 4 to 20 siloxane units is equal to or less than 0.1 mass %;
(B) an organopolysiloxane that contains in one molecule at least two silicon-bonded hydrogen atoms and that is free of an alkenyl group, a silicon-bonded hydroxyl group and a silicon-bonded alkoxy group;
(C) at least 0.05 parts by mass of an adhesion promoter;
(D) 100 to 2000 parts by mass of a thermally conductive filler; and
(E) a hydrosilylation-reaction catalyst, wherein
component (B) is contained in such an amount that the amount of silicon-bonded hydrogen atoms is in the range of 0.5 to 10 mol per 1 mol of the alkenyl groups of component (A), and
the sum of components (B) and (C) is 0.5 to 10 mass % of the sum of components (A), (B) and (C), and
the heating is performed in one of a vacuum environment and an evacuation environment.
